(19) United States
(12) Patent Application Publication
(10) Pub. No.: US 2009/0029529 A1
(43) Pub. Date: Jan. 29, 2009

(54) METHOD FOR CLEANING SEMICONDUCTOR DEVICE

(76) Inventor: Jong-Hun Shin, Siheung-si (KR)

Correspondence Address: SHERR & VAUGHN, PLLC, 620 HERNDON PARKWAY, SUITE 200, HERNDON, VA, 20170, US

(21) Appl. No.: 12/175,734

(22) Filed: Jul. 18, 2008

(30) Foreign Application Priority Data
Jul. 23, 2007 (KR) 10-2007-0073395

(51) Int. Cl. H01L 21/306; H01L 21/205

(52) U.S. Cl. 438/478; 134/1.2; 257/E21.102; 257/E21.226

(57) ABSTRACT

Disclosed is a method for cleaning a semiconductor device to remove native oxides or by-products created in the process of forming silicon germanium layers. The use of the method enables removal of native oxides or by-products created in the process of forming silicon germanium layers using hydrogen bromide and prevents reoxidation which may occur in subsequent processes after forming silicon germanium layers.

The present application claims priority under 35 U.S.C. 119 to Korean Patent Application No. 10-2007-0073395 (filed on Jul. 23, 2007), which is hereby incorporated by reference in its entirety.

### BACKGROUND

Recently, high-speed devices such as metal-oxide semiconductor field effect transistors (MOSFETs), modulation-doped field effect transistors (MODFETs) and high electron mobility transistors (HEMTs) have been suggested. These may use, in a channel region, a strained silicon (Si) layer obtained by incorporating a silicon germanium (SiGe) layer on a silicon substrate and then subjecting the SiGe layer to epitaxial growth. In field effect transistors (MOSFETs) utilizing the strained silicon layer, when a thin silicon channel is grown on the silicon germanium layer, the silicon is stretched to match the relatively large lattice constant of silicon germanium, which stresses the channel.

The intentional application of stress to silicon causes an increase in electron mobility, formation of quantum wells and improvement in electron transport. Accordingly, the use of the strained silicon layer for the channel region enables a 1.3 to 8-fold increase in speed, when compared to the use of non-strained silicon layers. Furthermore, unstrained Si substrates are used for a Czochralski method as a process, thus realizing high-speed CMOSs through a related CMOS process.

The epitaxial growth of a silicon germanium layer on the silicon layer to increase device speed involves formation of native oxides and by-products on silicon germanium. When using a cleaning process which removes the native oxides and by-products, it is important to maintain the characteristics of silicon germanium. Hydrofluoric acid (HF) or hydrochloric acid (HCl) exhibit superior removal efficiency when used for cleaning, but fluoride (F) cleaves bonds of silicon germanium. This disadvantageously modifies of characteristics of the silicon germanium, and may allow oxidation of the damaged surface upon exposure to air.

### SUMMARY

Embodiments relate to a method for cleaning a semiconductor device to remove native oxides or by-products created in the process of forming silicon germanium layers. Embodiments relate to a method for cleaning a semiconductor device suitable for removing native oxides or by-products created in the process of forming silicon germanium layers using hydrogen bromide. Embodiments relate to a method for cleaning a semiconductor device suitable for preventing reoxidation which may occur in subsequent processes after forming silicon germanium layers.

Embodiments relate to a method for cleaning a semiconductor device which includes forming a silicon germanium layer on a semiconductor substrate. The method also includes subjecting the silicon germanium layer to a plasma treatment to remove native oxides and by-products created by the formation of the silicon germanium layer. The method provides for cleaning the silicon germanium layer with de-ionized water.

### DRAWINGS

FIG. 1 is a view illustrating a method for cleaning a semiconductor device according to embodiments.

FIGS. 2A to 2F are sectional views illustrating the method for cleaning a semiconductor device according to embodiments.

### DESCRIPTION

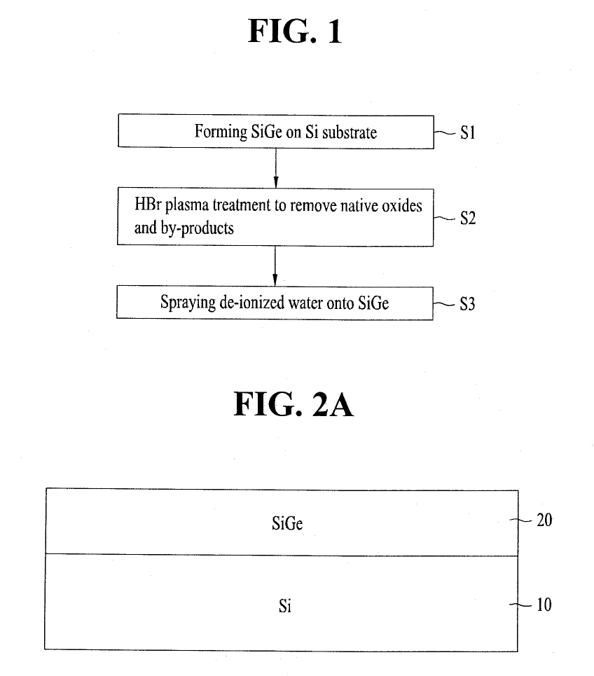

FIG. 1 is a flow chart illustrating a process for cleaning a semiconductor device according to embodiments. Referring to FIG. 1, in the method for cleaning a semiconductor device according to embodiments, a silicon germanium layer 20 is formed on a semiconductor substrate 10 (S1). The semiconductor substrate 10 may be a silicon substrate. The formation of the silicon germanium layer 20 on the semiconductor substrate 10 may involve formation of native oxides 30a and by-products 30b.

Subsequently, a plasma treatment may be performed to remove the native oxides 30a and by-products 30b (S2). The plasma treatment may be carried out using an HBr-containing gas mixture. After the plasma treatment, the silicon germanium layer 20 is cleaned with deionized water (S3). More specifically, the silicon germanium layer 20 is cleaned by spraying deionized water onto the surface of the silicon germanium layer 20.

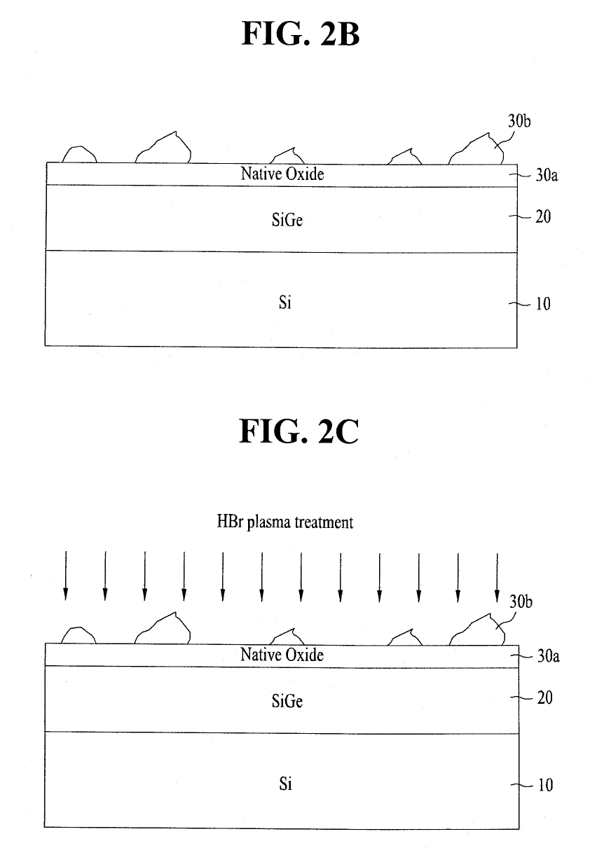

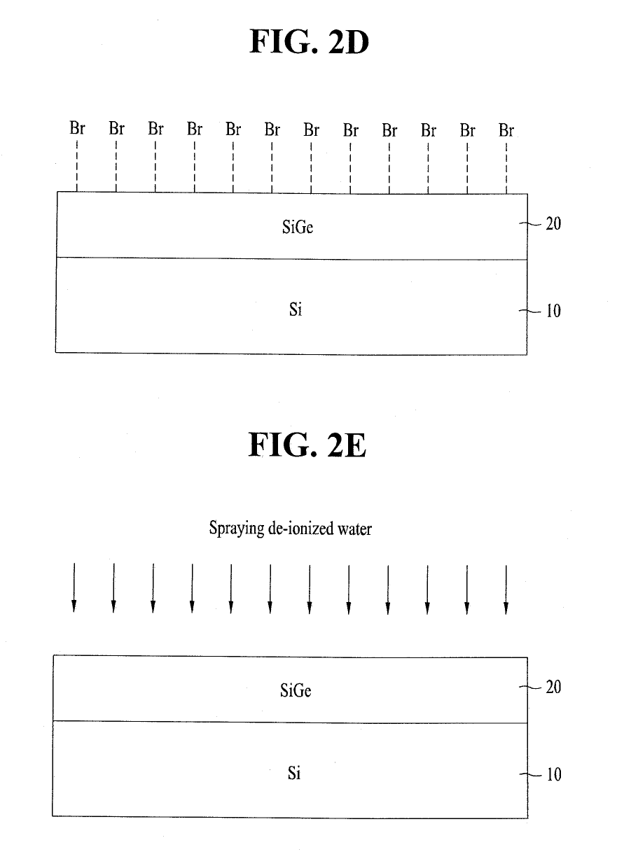

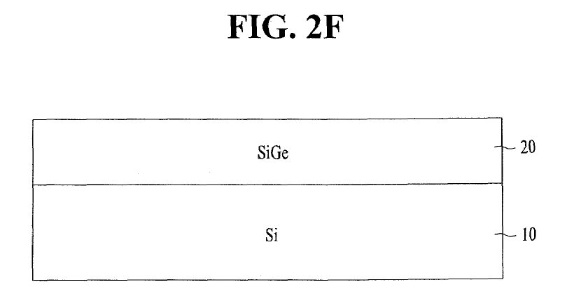

Hereinafter, the method for cleaning a semiconductor device according to embodiments will be illustrated in more detail with reference to FIGS. 2A to 2F. As shown in FIG. 2A, a silicon germanium (SiGe) layer 20 is formed on the semiconductor substrate 10. More specifically, the formation of the silicon germanium layer 20 may be carried out by first forming a germanium (Ge) fraction on the semiconductor substrate 10 and subjecting the germanium fraction to epitaxial growth at a high temperature and a high pressure. The silicon germanium layer 20 may be formed using a variety of methods including chemical vapor deposition (CVD), sputtering, vacuum deposition and molecular beam epitaxy (MBE). For many purposes, epitaxial growth using CVD may be advantageously used in the formation of the silicon germanium layer 20 (S1). The formation of the silicon germanium layer 20 may involve formation of native oxides 30a and by-products 30b on the silicon germanium layer 20 grown on the semiconductor substrate 10.

Subsequently, as shown in FIG. 2C, a plasma treatment may be performed on the silicon germanium layer 20 where by-products and native oxides are present, using a gas mixture. The gas mixture used for the plasma treatment may be a mixture of Ar and HBr. The plasma treatment may be carried out with HBr and Ar as process atmospheres, which are injected at a flow rate of 90 to 100 sccm and 400 to 500 sccm, respectively. An inner pressure may be set in a range of about 5 to 10 mTorr. A high frequency power may be set to a range of about 1,000 to 3,000 W, and a process time may be from about 30 to 60 seconds (S2).

In comparison to HF or HCl, the HBr used for plasma treatment has no substantial effect on germanium (Ge). Through the afore-mentioned plasma treatment, the native oxides can be removed. More specifically, the native oxides can be removed by ion bombardment of hydrogen (H) or bromine (Br). The bromine (Br) of hydrogen bromide (HBr) is bound to silicon (Si) to form silicon bromide (SiBr). The silicon bromide is thus removed in a gaseous state. When the gaseous silicon bromide is removed, the by-products can be removed by lift-off. In addition, since the surface of the silicon germanium layer 20 is treated with the hydrogen (H) of HBr, no re-oxidation occurs.

As shown in FIG. 2D, bromine (Br) remains on the surface of the silicon germanium layer 20 after the plasma treatment using HBr. Accordingly, as shown in FIG. 2E, the bromine (Br) residues present on the surface of the silicon germanium layer 20 are removed by spraying de-ionized water (DIW) onto the silicon germanium layer 20.

More specifically, the bromine (Br) residues present on the surface of the silicon germanium layer 20 may be removed as follows. First, the surface of the silicon germanium layer 20 is cleaned by performing quick drain rinse (hereinafter, referred to as “QDR”) in which DIW is rapidly ejected onto the silicon germanium layer 20. Subsequently, isopropyl alcohol (IPA) is sprayed onto the surface of the silicon germanium layer 20 to remove moisture present thereon. The removal of the bromine (Br) residues present on the surface of the silicon germanium layer 20 may be carried out by spraying DIW under a process atmosphere at a flow rate of about 20 to 40 mL/min, for a process time of about 150 to 300 seconds (S3). Consequently, via the plasma treatment and bromine removal, it is possible to remove native oxides and by-products created during growth of the silicon germanium layer 20 on the semiconductor substrate 10, while having no affect on the silicon germanium layer 20.

With the method for cleaning a semiconductor device according to embodiments, it is possible to remove native oxides and by-products created during growth of the silicon germanium layer 20 on the semiconductor substrate 10 via plasma treatment using hydrogen bromide (HBr). This treatment also substantially prevents reoxidation which may occur due to the native oxides and by-products in subsequent processes.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a silicon germanium layer on a semiconductor substrate;
subjecting the silicon germanium layer to a plasma treatment to remove native oxides and by-products created by the formation of the silicon germanium layer; and
cleaning the silicon germanium layer with de-ionized water.

2. The method of claim 1, wherein forming the silicon germanium layer includes:
forming a germanium fraction on the semiconductor substrate; and
subjecting the germanium fraction to epitaxial growth at a high temperature and a high pressure.

3. The method of claim 1, wherein the plasma treatment is performed on the silicon germanium layer including the native oxides and the by-products using a gas mixture of argon and hydrogen bromide.

4. The method of claim 3, wherein during the plasma treatment, bromine of the hydrogen bromide is bound to silicon to form silicon bromide and the silicon bromide is then removed in a gaseous state.

5. The method of claim 4, wherein when the silicon bromide is removed in a gaseous state, the by-products are removed by lift-off.

6. The method of claim 3, wherein during the plasma treatment, the silicon germanium layer is subjected to a hydrogen surface treatment to prevent reoxidation of the germanium layer.

7. The method of claim 1, wherein cleaning the silicon germanium layer with de-ionized water is carried out by rapidly spraying the de-ionized water onto the silicon germanium layer.

8. The method of claim 7, wherein bromine residues left on the surface of the silicon germanium layer after the plasma treatment are removed by spraying the de-ionized water.

9. The method of claim 1, wherein cleaning the surface of the silicon germanium layer with de-ionized water is carried out through a quick drain rinse performed by rapidly ejecting de-ionized water onto the surface of the silicon germanium layer.

10. The method of claim 1, comprising:
after cleaning the silicon germanium layer with de-ionized water, removing moisture present on the surface of the silicon germanium layer.

11. The method of claim 10, wherein the removal of moisture present on the surface of the silicon germanium layer is carried out by spraying isopropyl alcohol onto the silicon germanium layer.

12. The method of claim 3, wherein during the plasma treatment, hydrogen bromide is injected at a flow rate of approximately 90 to 100 sccm, argon is injected at a flow rate of approximately 400 to 500 sccm, an inner pressure is set in a range of approximately 5 to 10 mTorr, high frequency power is set to a range of approximately 1,000 to 3,000 W, and a process time is in a range of approximately 30 to 60 seconds.

13. A method comprising:
forming a silicon germanium layer on a silicon substrate, thereby forming native oxides and by-products;
subjecting the silicon germanium layer to a plasma treatment using a gas mixture containing argon and hydrogen bromide to remove native oxides and by-products created by the formation of the silicon germanium layer; and
cleaning the silicon germanium layer with de-ionized water.

14. The method of claim 13, wherein forming the silicon germanium layer includes:
forming a germanium fraction on the semiconductor substrate; and
subjecting the germanium fraction to epitaxial growth at a high temperature and a high pressure.

15. The method of claim 13, wherein during the plasma treatment, bromine of the hydrogen bromide is bound to silicon to form silicon bromide and the silicon bromide is then removed in a gaseous state.

16. The method of claim 15, wherein when the silicon bromide is removed in a gaseous state, the by-products are removed by lift-off.

17. The method of claim 13, wherein cleaning the silicon germanium layer with de-ionized water is carried out by rapidly spraying the de-ionized water onto the silicon germanium layer.

18. The method of claim 13, comprising:
after cleaning the silicon germanium layer with de-ionized water, removing moisture present on the surface of the silicon germanium layer by spraying isopropyl alcohol onto the silicon germanium layer.

19. The method of claim 13, wherein during the plasma treatment, hydrogen bromide is injected at a flow rate of approximately 90 to 100 sccm, argon is injected at a flow rate of approximately 400 to 500 sccm, an inner pressure is set in a range of approximately 5 to 10 mTorr, high frequency power is set to a range of approximately 1,000 to 3,000 W, and a process time is in a range of approximately 30 to 60 seconds.

20. The method of claim 17, wherein the de-ionized water is supplied at a flow rate of approximately 20 to 40 ml./min. for a process time of approximately 150 to 300 seconds.
